(19) United States
(12) Patent Application Publication
(10) Pub. No.: US 2024/0213061 A1
(43) Pub. Date: Jun. 27, 2024

(54) SEMICONDUCTOR WAFER DETECTION DEVICE AND DROPLET GUIDE MEMBER

(71) Applicant: EBARA CORPORATION, Tokyo (JP)

(72) Inventors: TOMOAKI FUJIMOTO, Tokyo (JP); KUNIMASA MATSUSHITA, Tokyo (JP)

(73) Assignee: EBARA CORPORATION, Tokyo (JP)

(21) Appl. No.: 18/389,669

(22) Filed: Dec. 19, 2023

(30) Foreign Application Priority Data
Dec. 21, 2022 (JP) 2022-203853

(51) Int. Cl. H01L 21/67

(52) U.S. Cl. CPC H01L 21/67259

(57) ABSTRACT

A semiconductor wafer detection device detects a semiconductor wafer. The semiconductor wafer detection device includes a light sensor, a detector, and a droplet guide member. The light sensor includes a light emitter having a light emitting surface that emits light, and a light receiver having a light receiving surface that receives the light from the light emitter. The detector detects the semiconductor wafer based on the light received by the light receiver. The droplet guide member causes a droplet adhering to the light emitting surface to flow down. The droplet guide member includes a liquid guide part of a plate shape. The liquid guide part is arranged with a tip facing the center of the light emitting surface when viewed in a direction of an optical axis of the light emitting surface.

### CROSS-REFERENCE TO RELATED APPLICATIONS

This application claims the priority benefit of Japan Application No. 2022-203853, filed on Dec. 21, 2022. The entirety of the above-mentioned patent application is hereby incorporated by reference herein and made a part of this specification.

### BACKGROUND

### Technical Field

The disclosure relates to a semiconductor wafer detection device and a droplet guide member.

### Related Art

In a semiconductor wafer manufacturing process, a semiconductor wafer can be detected using a detection device equipped with an optical sensor. The detection accuracy of the optical sensor may be reduced due to adhesion of water droplets to the optical sensor. Examples of methods for removing water droplets include a method in which a rod-shaped member is provided close to a target surface to thereby cause the water droplets adhering to the target surface to flow down along the member (for example, see Japanese Patent Laid-open No. 2015-46775).

However, in a semiconductor wafer detection device, even if the above-described method is adopted, it is difficult to suppress deterioration in detection accuracy due to water droplets (droplets).

### SUMMARY

A semiconductor wafer detection device according to one aspect of the disclosure is a semiconductor wafer detection device that detects a semiconductor wafer. The semiconductor wafer detection device includes: a light sensor, including a light emitter having a light emitting surface that emits light, and a light receiver having a light receiving surface that receives the light; a detector, detecting the semiconductor wafer based on the light received by the light receiver; and one or a plurality of droplet guide members, causing a droplet adhering to a sensor surface that is at least one of the light emitting surface and the light receiving surface to flow down. The droplet guide member includes a liquid guide part of a plate shape. The liquid guide part is arranged with a tip facing the center of the sensor surface when viewed in an optical axis direction of the sensor surface.

### BRIEF DESCRIPTION OF THE DRAWINGS

FIG. 1 is a side view illustrating a semiconductor wafer detection device according to a first embodiment.

FIG. 2 is a side view illustrating a light emitter and a droplet guide member.

FIG. 3 is an enlarged side view illustrating the light emitter and the droplet guide member.

FIG. 4 is an enlarged plan view illustrating the light emitter and the droplet guide member.

FIG. 5 is an enlarged perspective view illustrating the light emitter and the droplet guide member.

FIG. 6 is a side view illustrating a light receiver and the droplet guide member.

FIG. 7 is an enlarged plan view illustrating the light receiver and the droplet guide member.

FIG. 8 is an enlarged perspective view illustrating the light receiver and the droplet guide member.

FIG. 9 is an explanatory diagram illustrating a movement of a water droplet at the light emitter.

FIG. 10 is an explanatory diagram illustrating a movement of the water droplet at the light emitter.

FIG. 11 is an explanatory diagram illustrating a movement of the water droplet at the light emitter.

FIG. 12 is an explanatory diagram illustrating a movement of the water droplet at the light receiver.

FIG. 13 is an explanatory diagram illustrating a movement of the water droplet at the light receiver.

FIG. 14 is an explanatory diagram illustrating a movement of the water droplet at the light receiver.

FIG. 15 is a side view partially illustrating a semiconductor wafer detection device according to a second embodiment.

FIG. 16 is a side view partially illustrating the semiconductor wafer detection device according to the second embodiment.

FIG. 17 is a side view partially illustrating a semiconductor wafer detection device according to a third embodiment.

FIG. 18 is a side view partially illustrating a semiconductor wafer detection device according to a fourth embodiment.

FIG. 19 is a side view partially illustrating a semiconductor wafer detection device according to a fifth embodiment.

FIG. 20 is a side view partially illustrating a semiconductor wafer detection device according to a sixth embodiment.

### DESCRIPTION OF THE EMBODIMENTS

The disclosure provides a semiconductor wafer detection device and a droplet guide member in which deterioration in detection accuracy due to droplets can be suppressed.

A semiconductor wafer detection device according to a first aspect of the disclosure is a semiconductor wafer detection device that detects a semiconductor wafer. The semiconductor wafer detection device includes: a light sensor, including a light emitter having a light emitting surface that emits light, and a light receiver having a light receiving surface that receives the light; a detector, detecting the semiconductor wafer based on the light received by the light receiver; and one or a plurality of droplet guide members, causing a droplet adhering to a sensor surface that is at least one of the light emitting surface and the light receiving surface to flow down. The droplet guide member includes a liquid guide part of a plate shape. The liquid guide part is arranged with a tip facing the center of the sensor surface when viewed in an optical axis direction of the sensor surface.

According to a second aspect of the disclosure, in the semiconductor wafer detection device according to the first aspect, a portion of the liquid guide part that includes at least the tip overlaps the sensor surface when viewed in the optical axis direction.

According to a third aspect of the disclosure, in the semiconductor wafer detection device according to the first or second aspect, a facing surface of the liquid guide part facing the sensor surface is an inclined surface that descends in a direction away from the sensor surface.

According to a fourth aspect of the disclosure, in the semiconductor wafer detection device according to any one of the first to third aspects, the liquid guide part is formed in a blade shape whose thickness decreases toward the tip.

According to a fifth aspect of the disclosure, the semiconductor wafer detection device according to any one of the first to fourth aspects further includes a spraying mechanism that sprays a gas in a direction approaching the liquid guide part when viewed in the optical axis direction onto the sensor surface.

According to a sixth aspect of the disclosure, the semiconductor wafer detection device according to any one of the first to fifth aspects further includes a support that supports both the light emitter and the light receiver.

A droplet guide member according to a seventh aspect of the disclosure is used in a semiconductor wafer detection device equipped with a light sensor and a detector. The light sensor includes a light emitter having a light emitting surface that emits light and a light receiver having a light receiving surface that receives the light. The detector detects a semiconductor wafer based on the light received by the light receiver. The droplet guide member includes a liquid guide part of a plate shape. The liquid guide part is arranged with a tip facing the center of a sensor surface that is at least one of the light emitting surface and the light receiving surface when viewed in an optical axis direction of the sensor surface.

According to one aspect of the disclosure, a semiconductor wafer detection device and a droplet guide member can be provided in which deterioration in detection accuracy due to droplets can be suppressed.

Hereinafter, a semiconductor wafer detection device according to an embodiment of the disclosure will be described based on the drawings.

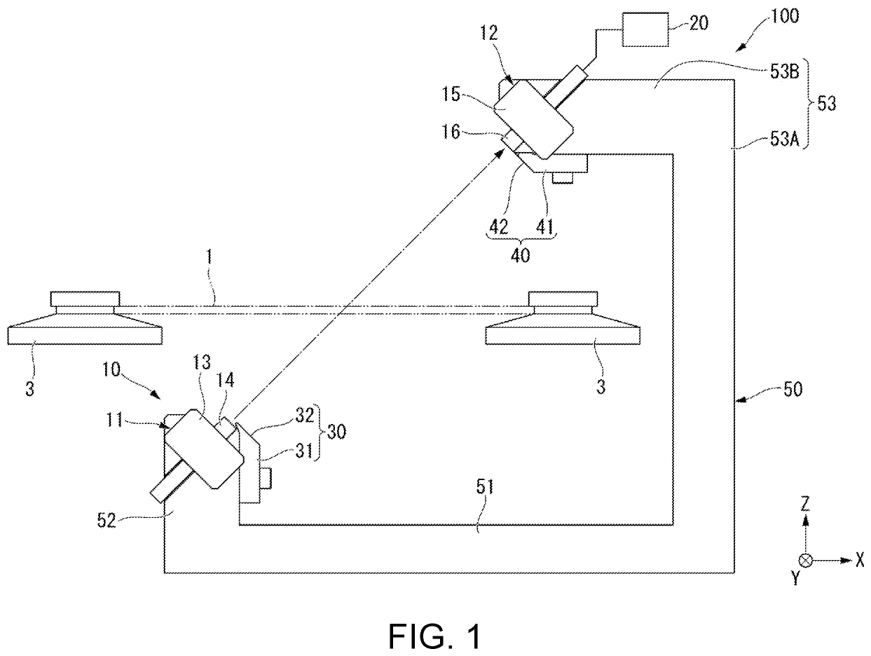

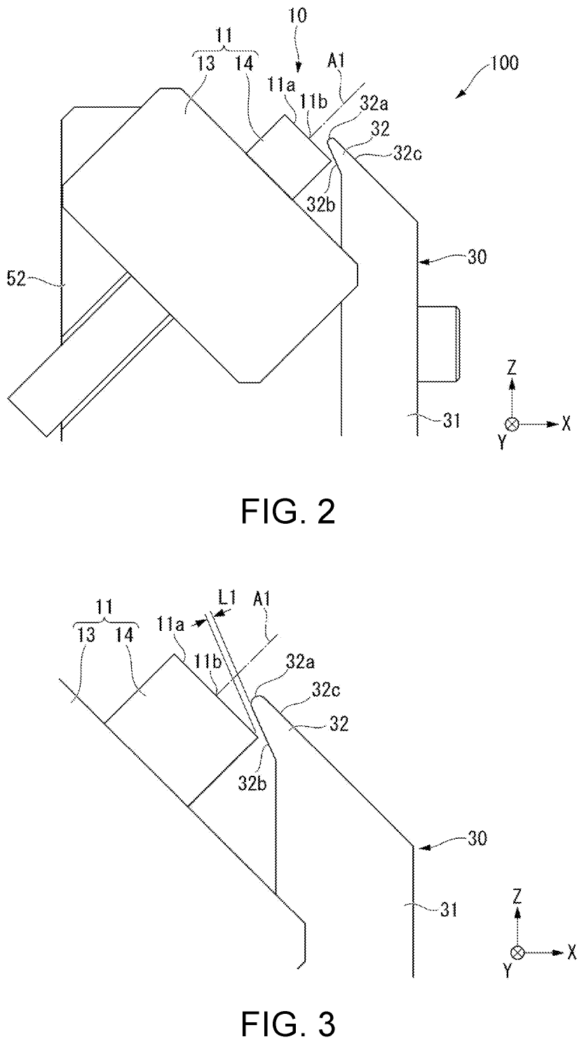

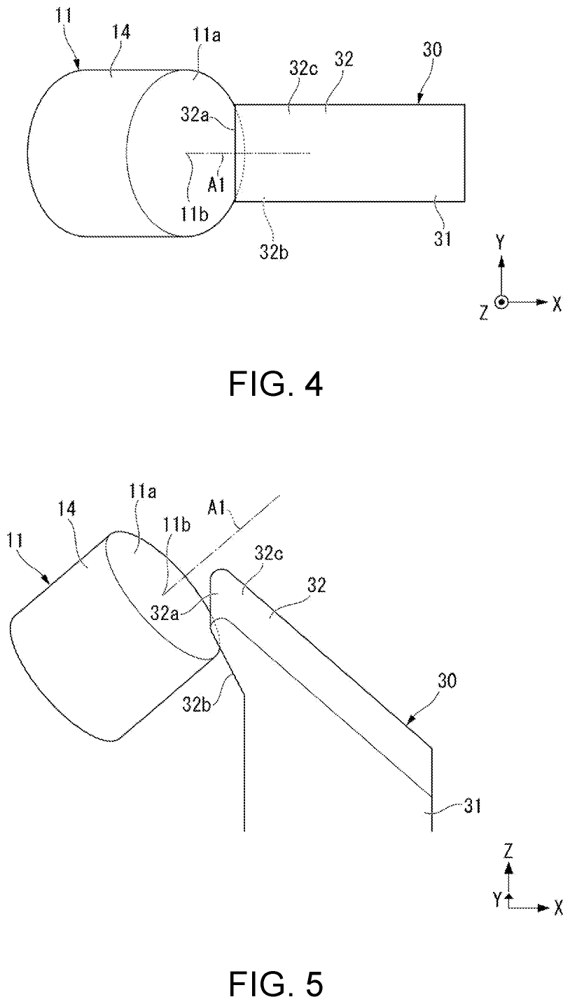

FIG. 1 is a side view illustrating a semiconductor wafer detection device 100 according to a first embodiment. FIG. 2 is a side view illustrating a light emitter 11 and a first droplet guide member 30. FIG. 3 is an enlarged side view illustrating the light emitter 11 and the first droplet guide member 30. FIG. 4 is an enlarged plan view illustrating the light emitter 11 and the first droplet guide member 30. FIG. 5 is an enlarged perspective view illustrating the light emitter 11 and the first droplet guide member 30.

### Semiconductor Wafer Detection Device (First Embodiment)

As illustrated in FIG. 1, the semiconductor wafer detection device 100 according to the present embodiment includes: a light sensor 10, a detector 20, the first droplet guide member 30, a second droplet guide member 40, and a support 50. Hereinafter, the first droplet guide member 30 and the second droplet guide member 40 May be collectively referred to as “droplet guide members 30 and 40.”

A left-right direction in FIG. 1 is a left-right direction X. An up-down direction in FIG. 1 is an up-down direction Z. A direction orthogonal to the left-right direction X and the up-down direction Z is a front-rear direction Y. The right side in FIG. 1 is a +X direction. The left side in FIG. 1 is a −X direction. The left-right direction X is, for example, a horizontal direction. The up-down direction Z is, for example, a vertical direction. The up-down direction Z may be inclined with respect to the vertical direction. The left-right direction X and the front-rear direction Y may be inclined with respect to the horizontal direction.

The light sensor 10 includes the light emitter 11 and a light receiver 12.

As illustrated in FIG. 2, the light emitter 11 includes a base 13 (bracket) and a tip part 14 (sensor head). The base 13 is formed in a block shape. The tip part 14 protrudes from the base 13. A protrusion direction (direction of a central axis) of the tip part 14 is a diagonally upward direction (ascending direction toward the right side). The light emitter 11 includes a light emitting element such as a light emitting diode (LED).

As illustrated in FIG. 3 to FIG. 5, the tip part 14 is formed in, for example, a columnar shape. A tip surface of the tip part 14 is a light emitting surface 11a that emits light. The light emitting surface 11a is, for example, a circular flat surface. The light emitting surface 11a is orthogonal to the central axis of the tip part 14. The light emitting surface 11a is an example of a “sensor surface.” The light emitter 11 emits light in a direction orthogonal to the light emitting surface 11a. The direction of the central axis of the tip part 14 is a direction of an optical axis A1 of the light emitter 11. The optical axis A1 is inclined with respect to the vertical direction. The direction of the optical axis A1 is an example of an “optical axis direction.”

As illustrated in FIG. 3, the light emitting surface 11a is inclined with respect to a horizontal plane. In FIG. 2 and FIG. 3, the light emitting surface 11a is an inclined surface that descends toward the right side (+X direction).

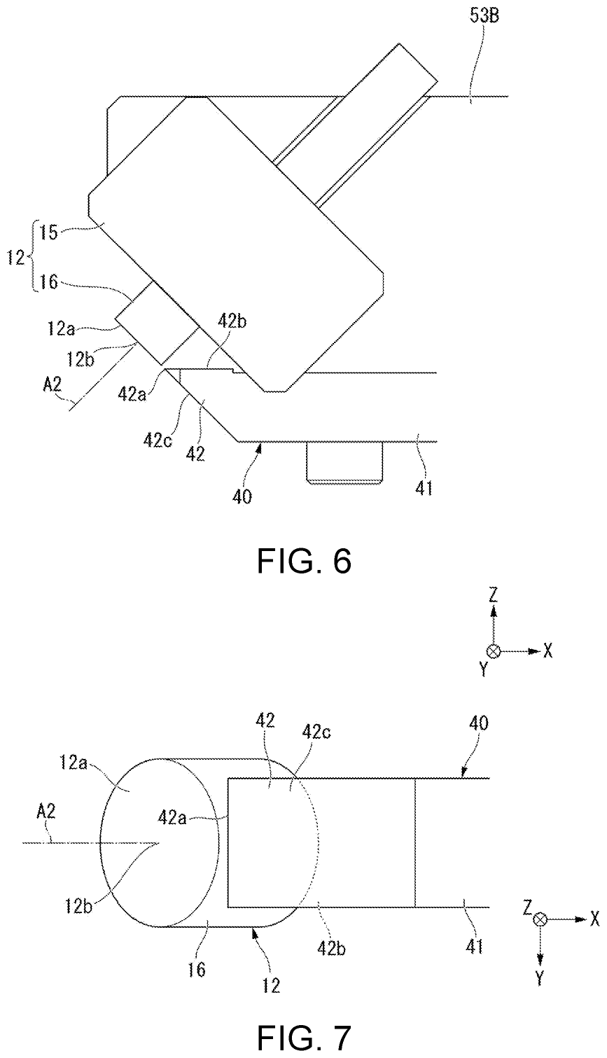

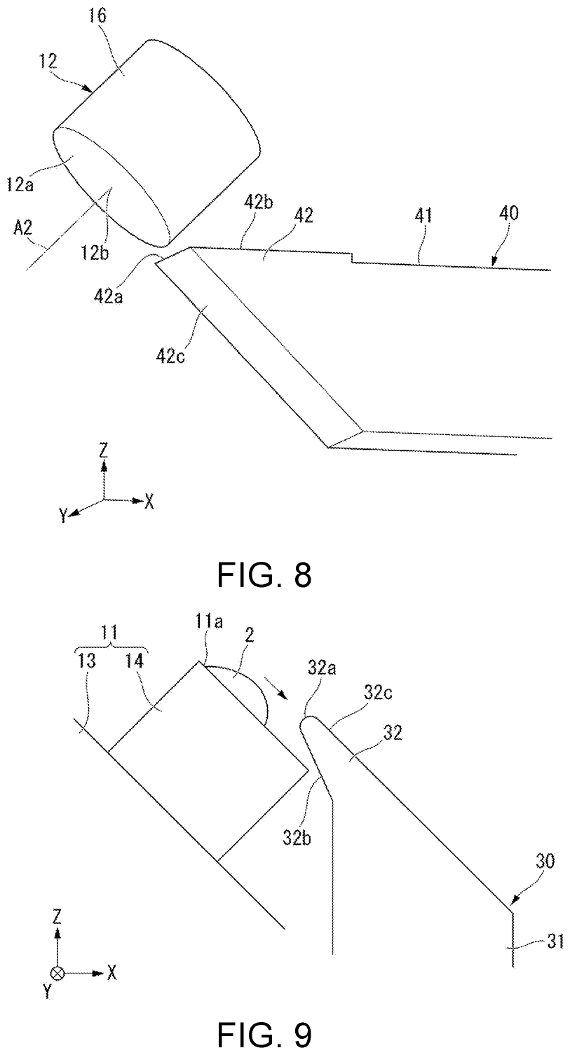

FIG. 6 is a side view illustrating the light receiver 12 and the second droplet guide member 40. FIG. 7 is an enlarged plan view illustrating the light receiver 12 and the second droplet guide member 40. FIG. 8 is an enlarged perspective view illustrating the light receiver 12 and the second droplet guide member 40.

As illustrated in FIG. 6, the light receiver 12 includes a base 15 (bracket) and a tip part 16 (sensor head). The base 15 is formed in a block shape. The tip part 16 protrudes from the base 15. A protrusion direction (direction of a central axis) of the tip part 16 is a diagonally downward direction (descending direction toward the left side). The light receiver 12 includes a light receiving element such as a phototransistor or a photodiode.

As illustrated in FIG. 7 and FIG. 8, the tip part 16 is formed in, for example, a columnar shape. A tip surface of the tip part 16 is a light receiving surface 12a that receives the light from the light emitter 11. The light receiving surface 12a is, for example, a circular flat surface. The light receiving surface 12a is orthogonal to the central axis of the tip part 16. The light receiving surface 12a is an example of a “sensor surface.”

A direction in which the light from the light emitter 11 enters the light receiver 12 is a direction orthogonal to the light receiving surface 12a. The direction of the central axis of the tip part 16 is a direction of an optical axis A2 of the light receiver 12. The optical axis A2 is inclined with respect to the vertical direction. The optical axis A2 matches the optical axis A1 of the light emitter 11. The direction of the optical axis A2 is an example of an “optical axis direction.”

As illustrated in FIG. 6, the light receiving surface 12a is inclined with respect to the horizontal plane. In FIG. 6, the light receiving surface 12a is an inclined surface that descends toward the right side (+X direction).

As illustrated in FIG. 1, the light receiving surface 12a is located away from the light emitting surface 11a of the light emitter 11 in the +X direction when viewed in the up-down direction Z.

The light from the light emitter 11 is emitted in a diagonally upward direction (direction in which the light is inclined to ascend as it goes in the +X direction) and heads toward the light receiver 12.

In the case where a semiconductor wafer 1 is present between the light emitter 11 and the light receiver 12, the light heading toward the light receiver 12 from the light emitter 11 is blocked. Hence, the amount of the light entering the light receiver 12 is relatively small. In the case where the semiconductor wafer 1 is not present between the light emitter 11 and the light receiver 12, the light heading toward the light receiver 12 from the light emitter 11 is not blocked. Hence, the amount of the light entering the light receiver 12 is relatively large.

The detector 20 is able to detect the semiconductor wafer 1 based on the amount of the light received by the light receiver 12. For example, in the case where the amount of the light received by the light receiver 12 is lower than a predetermined value, the detector 20 determines that the semiconductor wafer 1 is present. In the case where the amount of the light received by the light receiver 12 is higher than or equal to the predetermined value, the detector 20 determines that the semiconductor wafer 1 is not present.

The support 50 supports the light emitter 11 and the light receiver 12. The support 50 includes a base 51, a first support frame 52, and a second support frame 53.

The base 51 is, for example, a frame extending in one direction. The base 51 extends in, for example, the left-right direction X.

The first support frame 52 extends upward from one end (for example, a left end in FIG. 1) of the base 51. The first support frame 52 supports the light emitter 11 and the first droplet guide member 30.

The second support frame 53 includes a pillar 53A and an extension frame 53B. The pillar 53A is a frame that extends upward from the other end (for example, a right end in FIG. 1) of the base 51. The extension frame 53B extends laterally (to the left side in FIG. 1) from an upper end of the pillar 53A. The extension frame 53B supports the light receiver 12 and the second droplet guide member 40. Since the pillar 53A is longer than the first support frame 52, the light receiving surface 12a of the light receiver 12 is located at a high position with respect to the light emitting surface 11a of the light emitter 11.

The base 51, the first support frame 52, and the second support frame 53 can be, for example, integrally formed. The support 50 is made of, for example, metal or resin.

### Droplet Guide Member

As illustrated in FIG. 2 and FIG. 3, the first droplet guide member 30 includes a base part 31 and a liquid guide part 32. The first droplet guide member 30 is an example of a “droplet guide member.”

The base part 31 is formed in, for example, a prism shape or a plate shape. The base part 31 extends in the up-down direction Z. The base part 31 overlaps a side surface of the first support frame 52 of the support 50. The base part 31 is fixed to the first support frame 52 by screw fastening or the like.

As illustrated in FIG. 3, the liquid guide part 32 is formed in, for example, a plate shape. Specifically, the liquid guide part 32 is formed in a blade shape. The “blade shape” is a plate shape whose thickness decreases toward a tip 32a. The liquid guide part 32 extends from an upper end of the base part 31. An extension direction of the liquid guide part 32 is a direction inclined with respect to the up-down direction Z. The liquid guide part 32 is inclined and extends from the upper end of the base part 31 in a direction approaching the tip part 14 of the light emitter 11. A width direction of the liquid guide part 32 is parallel to the front-rear direction Y.

A facing surface 32b of the liquid guide part 32 is a surface facing the tip part 14 of the light emitter 11. The facing surface 32b is a flat surface. The facing surface 32b is a surface inclined with respect to the up-down direction Z. Specifically, the facing surface 32b is inclined in the direction approaching the tip part 14 toward the tip 32a. The facing surface 32b is an inclined surface that descends in a direction away from the light emitting surface 11a. In FIG. 3, the facing surface 32b is an inclined surface that descends toward the right side (+X direction).

An inclination angle of the facing surface 32b with respect to the up-down direction Z is smaller than an inclination angle of the light emitting surface 11a with respect to the up-down direction Z. Hence, when viewed in the direction of the optical axis A1, a region in the facing surface 32b that overlaps the light emitting surface 11a has a greater distance from the light emitting surface 11a closer to the tip 32a.

A surface opposite to the facing surface 32b is an outer surface 32c. The outer surface 32c has a larger inclination angle with respect to the up-down direction Z than the facing surface 32b. The outer surface 32c is a flat surface. Since the inclination angle of the outer surface 32c is larger than the inclination angle of the facing surface 32b, the liquid guide part 32 has a plate shape (blade shape) whose thickness decreases toward the tip 32a.

As illustrated in FIG. 4 and FIG. 5, the liquid guide part 32 is arranged in a posture with the tip 32a facing a center 11b of the light emitting surface 11a when viewed in the direction of the optical axis A1 of the light emitting surface 11a. When viewed in the direction of the optical axis A1, the liquid guide part 32 does not reach the center 11b. Since the center 11b does not overlap the liquid guide part 32, the light emitted from the light emitting surface 11a is hardly obstructed by the liquid guide part 32.

A portion of the liquid guide part 32 that includes at least a portion of the tip 32a overlaps the light emitting surface 11a when viewed in the direction of the optical axis A1 of the light emitting surface 11a. Specifically, the portion of the liquid guide part 32 that includes the tip 32a is located at a position overlapping the light emitting surface 11a when viewed in the direction of the optical axis A1 of the light emitting surface 11a. A region in the facing surface 32b that includes the tip 32a faces the light emitting surface 11a.

In the present embodiment, the tip 32a is located at a position overlapping the light emitting surface 11a over the entire width when viewed in the direction of the optical axis A1. However, the tip 32a may be located at a position where only a portion of the tip 32a in the width direction (front-rear direction Y) overlaps the light emitting surface 11a when viewed in the direction of the optical axis A1.

As illustrated in FIG. 3, the portion of the liquid guide part 32 that includes the tip 32a is located away from the light emitting surface 11a. A distance L1 between the liquid guide part 32 and the light emitting surface 11a is the shortest distance between the liquid guide part 32 and the light emitting surface 11a.

The distance L1 between the liquid guide part 32 and the light emitting surface 11a is preferably 1 mm or more and 2 mm or less. If the distance L1 is 1 mm or more, since a gap can be secured between the liquid guide part 32 and the light emitting surface 11a, a water droplet (droplet) easily flows out from the light emitting surface 11a through this gap. If the distance L1 is 2 mm or less, since a water droplet adhering to the light emitting surface 11a easily comes into contact with the liquid guide part 32, outflow of the water droplet can be facilitated.

A suitable range of the distance L1 varies depending on the material of the light emitting surface 11a, the type of droplets (for example, component of chemical solution), and the like.

As illustrated in FIG. 6, the second droplet guide member 40 includes a base part 41 and a liquid guide part 42. The second droplet guide member 40 is an example of a “droplet guide member.”

The base part 41 is formed in, for example, a prism shape or a plate shape. The base part 41 extends in the left-right direction X (horizontal direction). The base part 41 overlaps a side surface of the extension frame 53B of the support 50. The base part 41 is fixed to the extension frame 53B by screw fastening or the like.

The liquid guide part 42 is formed in a plate shape. Specifically, the liquid guide part 42 is formed in a blade shape. The “blade shape” is a plate shape whose thickness decreases toward a tip 42a. The liquid guide part 42 extends from a tip of the base part 41 in a direction approaching the tip part 16 of the light receiver 12. A width direction of the liquid guide part 42 is parallel to the front-rear direction Y.

A facing surface 42b of the liquid guide part 42 is a surface facing the tip part 16 of the light receiver 12. The facing surface 42b is a flat surface. The facing surface 42b is a surface along the left-right direction X (horizontal direction).

A surface opposite to the facing surface 42b is an outer surface 42c. The outer surface 42c is inclined with respect to the facing surface 42b. The outer surface 42c is a flat surface. Since the outer surface 42c is inclined with respect to the facing surface 42b, the liquid guide part 42 has a plate shape (blade shape) whose thickness decreases toward the tip 42a. In FIG. 6, the outer surface 42c is an inclined surface that descends toward the right side (+X direction). An inclination angle of the outer surface 42c may be the same as an inclination angle of the light receiving surface 12a. It is desirable that the outer surface 42c be on the same plane as the light receiving surface 12a.

As illustrated in FIG. 7 and FIG. 8, the liquid guide part 42 is arranged in a posture with the tip 42a facing a center 12b of the light receiving surface 12a when viewed in the direction of the optical axis A2 of the light receiving surface 12a. A portion of the liquid guide part 42 that includes at least the tip 42a does not overlap the light receiving surface 12a when viewed in the direction of the optical axis A2 of the light receiving surface 12a. The tip 42a is located at a position close to the light receiving surface 12a when viewed in the direction of the optical axis A2. The tip 42a may be located at a position adjacent to the light receiving surface 12a or may be located at a position away from the light receiving surface 12a when viewed in the direction of the optical axis A2. In the present embodiment, the tip 42a is located at the position away from the light receiving surface 12a when viewed in the direction of the optical axis A2.

### Water Droplet Removal in Semiconductor Wafer Detection Device of Embodiment

Next, an example of water droplet removal in the semiconductor wafer detection device 100 is described.

As illustrated in FIG. 1, the semiconductor wafer detection device 100 is used in a cleaning device that cleans the semiconductor wafer 1, a polishing device that polishes the semiconductor wafer 1, a conveyance device that conveys the semiconductor wafer 1, or the like. In FIG. 1, the semiconductor wafer 1 is held by a holder 3. A liquid such as cleaning water may adhere as droplets (water droplets) to the light emitter 11 and the light receiver 12.

FIG. 9 to FIG. 11 are explanatory diagrams illustrating a movement of a water droplet at the light emitter 11.

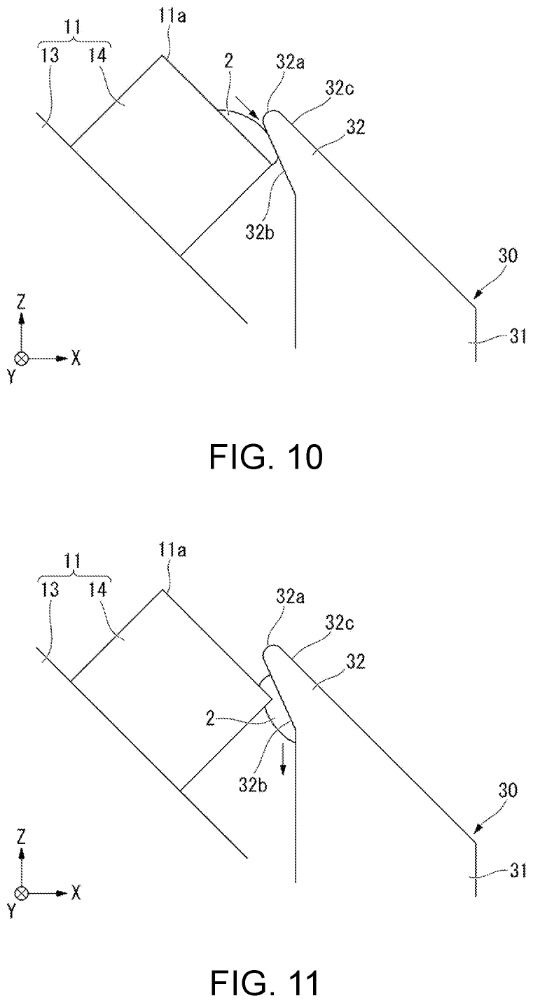

As illustrated in FIG. 9, it is assumed that a water droplet 2 adheres to the light emitting surface 11a of the light emitter 11. As illustrated in FIG. 10, the water droplet 2 flows down along the inclination of the light emitting surface 11a, and contacts the facing surface 32b of the liquid guide part 32 of the first droplet guide member 30. As illustrated in FIG. 11, the water droplet 2 further flows down along the inclination of the facing surface 32b and is discharged from the light emitting surface 11a.

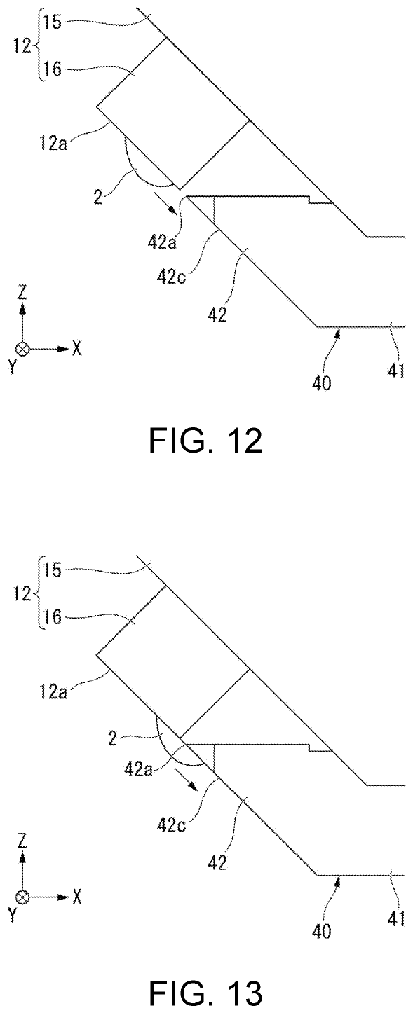

FIG. 12 to FIG. 14 are explanatory diagrams illustrating a movement of a water droplet at the light receiver 12.

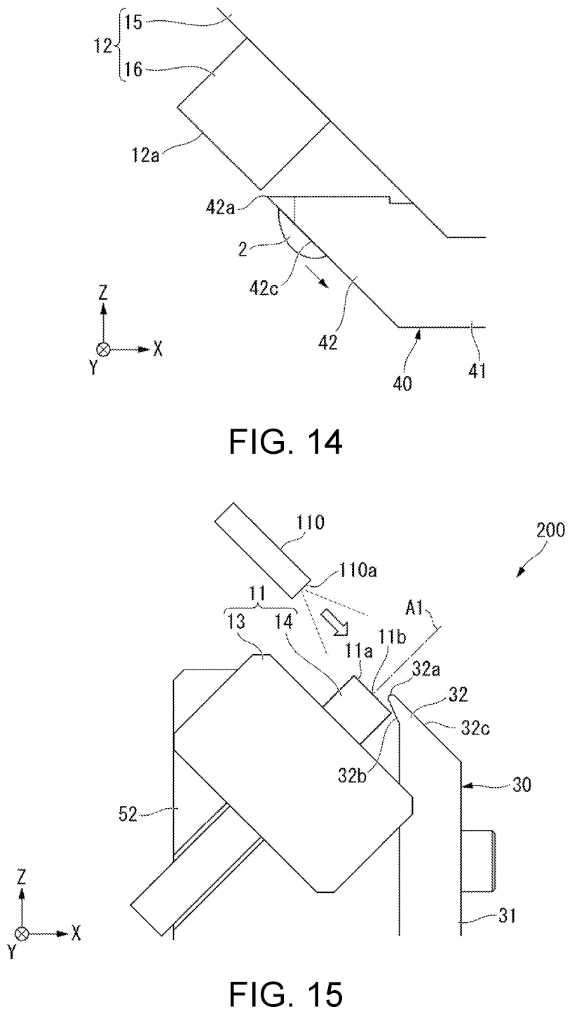

As illustrated in FIG. 12, it is assumed that the water droplet 2 adheres to the light receiving surface 12a of the light receiver 12. As illustrated in FIG. 13, the water droplet 2 flows down along the inclination of the light receiving surface 12a, and contacts the outer surface 42c of the liquid guide part 42 of the second droplet guide member 40. As illustrated in FIG. 14, the water droplet 2 further flows down along the inclination of the outer surface 42c and is discharged from the light receiving surface 12a.

### Effects Achieved by Semiconductor Wafer Detection Device of Embodiment

The semiconductor wafer detection device 100 includes the first droplet guide member 30 and the second droplet guide member 40. The liquid guide part 32 of the first droplet guide member 30 is arranged with the tip 32a facing the center 11b of the light emitting surface 11a when viewed in the direction of the optical axis A1. Hence, the water droplet 2 adhering to the light emitting surface 11a flows down along the liquid guide part 32 and is discharged from the light emitting surface 11a. Since the liquid guide part 32 is of a plate shape, the water droplet 2 can be removed over a wide range on the light emitting surface 11a. Accordingly, deterioration in detection accuracy due to the water droplet 2 adhering to the light emitting surface 11a can be suppressed.

The liquid guide part 42 of the second droplet guide member 40 is arranged with the tip 42a facing the center 12b of the light receiving surface 12a when viewed in the direction of the optical axis A2. Hence, the water droplet 2 adhering to the light receiving surface 12a flows down along the liquid guide part 42 and is discharged from the light receiving surface 12a. Since the liquid guide part 42 is of a plate shape, the water droplet 2 can be removed over a wide range on the light receiving surface 12a. Accordingly, deterioration in detection accuracy due to the water droplet 2 adhering to the light receiving surface 12a can be suppressed.

In the first droplet guide member 30, the portion of the liquid guide part 32 that includes at least the tip 32a overlaps the light emitting surface 11a when viewed in the direction of the optical axis A1. Hence, the water droplet 2 can be brought into contact with the facing surface 32b and be caused to flow down.

In the first droplet guide member 30, since the facing surface 32b of the liquid guide part 32 is an inclined surface that descends in the direction away from the light emitting surface 11a, the water droplet 2 can be efficiently caused to flow down along the facing surface 32b.

The semiconductor wafer detection device 100 includes the support 50 that supports both the light emitter 11 and the light receiver 12. Since the light emitter 11 and the light receiver 12 are supported in common by the support 50, relative positions of the light emitter 11 and the light receiver 12 can be made stable. Accordingly, deterioration in detection accuracy can be suppressed.

The liquid guide parts 32 and 42 are formed in a blade shape whose thickness decreases toward the tips 32a and 42a, respectively. By adopting this shape in the liquid guide parts 32 and 42, end faces of the tips 32a and 42a can be reduced in thickness. Hence, the amount of the water droplet 2 adhering to the end faces of the tips 32a and 42a can be reduced. Accordingly, the amount of the water droplet 2 adhering to the light emitting surface 11a and the light receiving surface 12a can be reduced.

### Effects Achieved by Droplet Guide Member of Embodiment

In the first droplet guide member 30, the liquid guide part 32 is arranged with the tip 32a facing the center 11b of the light emitting surface 11a when viewed in the direction of the optical axis A1. Hence, the water droplet 2 adhering to the light emitting surface 11a flows down along the liquid guide part 32 and is discharged from the light emitting surface 11a. Since the liquid guide part 32 is of a plate shape, the water droplet 2 can be removed over a wide range on the light emitting surface 11a.

In the second droplet guide member 40, the liquid guide part 42 is arranged with the tip 42a facing the center 12b of the light receiving surface 12a when viewed in the direction of the optical axis A2. Hence, the water droplet 2 adhering to the light receiving surface 12a flows down along the liquid guide part 42 and is discharged from the light receiving surface 12a. Since the liquid guide part 42 is of a plate shape, the water droplet 2 can be removed over a wide range on the light receiving surface 12a.

### Semiconductor Wafer Detection Device (Second Embodiment)

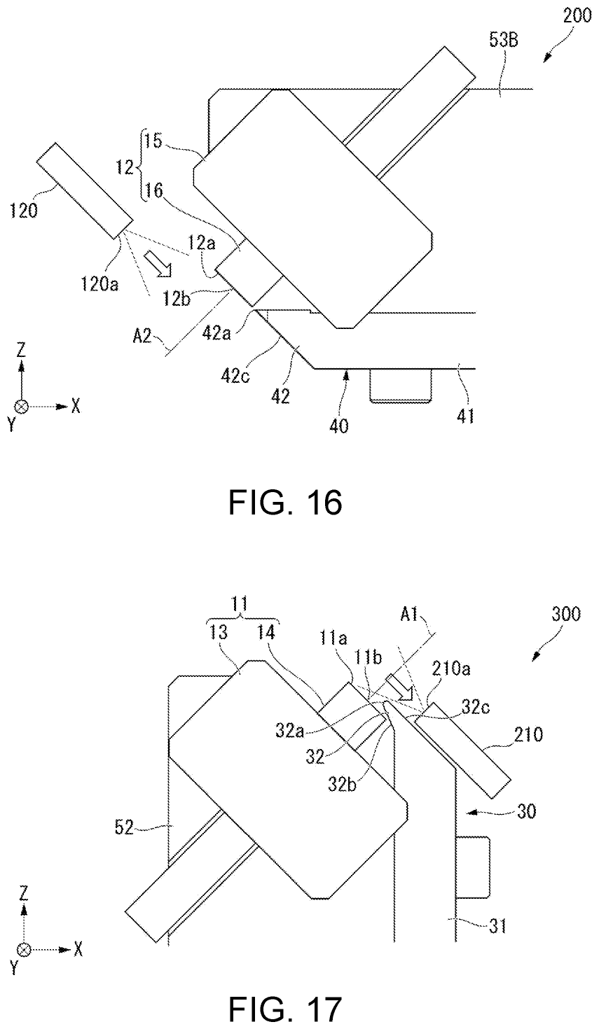

FIG. 15 and FIG. 16 are side views partially illustrating a semiconductor wafer detection device 200 according to a second embodiment.

As illustrated in FIG. 15 and FIG. 16, the semiconductor wafer detection device 200 according to the present embodiment includes, in addition to the components of the semiconductor wafer detection device 100 (see FIG. 1), a first spraying mechanism 110 and a second spraying mechanism 120. The first spraying mechanism 110 and the second spraying mechanism 120 are examples of a “spraying mechanism.”

The first spraying mechanism 110 is, for example, a cylinder having a gas communication hole. The first spraying mechanism 110 is able to spray a gas from an opening at a tip 110a. The first spraying mechanism 110 is provided in the vicinity of the light emitter 11. The first spraying mechanism 110 is arranged in a posture with the tip 110a facing in a direction approaching the liquid guide part 32 when viewed in the direction of the optical axis A1. Specifically, the tip 110a of the first spraying mechanism 110 is directed in a direction toward the tip 32a of the liquid guide part 32 from the center 11b of the light emitting surface 11a when viewed in the direction of the optical axis A1. A tip direction of the first spraying mechanism 110 is opposite to a tip direction of the liquid guide part 32 when viewed in the direction of the optical axis A1. Accordingly, the first spraying mechanism 110 is able to spray the gas in the direction approaching the liquid guide part 32 onto the light emitting surface 11a.

The second spraying mechanism 120 is, for example, a cylinder having a gas communication hole. The second spraying mechanism 120 is able to spray a gas from an opening at a tip 120a. The second spraying mechanism 120 is provided in the vicinity of the light receiver 12. The second spraying mechanism 120 is arranged in a posture with the tip 120a facing in a direction approaching the liquid guide part 42 when viewed in the direction of the optical axis A2. Specifically, the tip 120a of the second spraying mechanism 120 is directed in a direction toward the tip 42a of the liquid guide part 42 from the center 12b of the light receiving surface 12a when viewed in the direction of the optical axis A2. A tip direction of the second spraying mechanism 120 is opposite to a tip direction of the liquid guide part 42 when viewed in the direction of the optical axis A2. Accordingly, the second spraying mechanism 120 is able to spray the gas in the direction approaching the liquid guide part 42 onto the light receiving surface 12a.

Examples of the gas sprayed by the first spraying mechanism 110 and the second spraying mechanism 120 include air and nitrogen. An air pump or the like can be used as a supply source of the gas.

### Effects Achieved by Semiconductor Wafer Detection Device of Embodiment

In the semiconductor wafer detection device 200, the first spraying mechanism 110 sprays the gas in the direction approaching the liquid guide part 32 onto the light emitting surface 11a. Hence, movement of a water droplet toward the liquid guide part 32 can be facilitated by the pressure of the gas. Accordingly, deterioration in detection accuracy due to the water droplet adhering to the light emitting surface 11a can be suppressed.

The second spraying mechanism 120 sprays the gas in the direction approaching the liquid guide part 42 onto the light receiving surface 12a. Hence, movement of a water droplet toward the liquid guide part 42 can be facilitated by the pressure of the gas. Accordingly, deterioration in detection accuracy due to the water droplet adhering to the light receiving surface 12a can be suppressed.

In the semiconductor wafer detection device 200, the light emitting surface 11a and the light receiving surface 12a are inclined with respect to the horizontal plane. However, in the case where the spraying mechanisms 110 and 120 are used, water droplets can be removed even if the light emitting surface and the light receiving surface are not inclined with respect to the horizontal plane.

### Semiconductor Wafer Detection Device (Third Embodiment)

FIG. 17 is a side view partially illustrating a semiconductor wafer detection device 300 according to a third embodiment.

As illustrated in FIG. 17, the semiconductor wafer detection device 300 according to the present embodiment includes, in addition to the components of the semiconductor wafer detection device 100 (see FIG. 1), a suction mechanism 210.

The suction mechanism 210 is, for example, a cylinder having a gas communication hole. The suction mechanism 210 is able to suction a gas from an opening at a tip 210a. The suction mechanism 210 is provided in the vicinity of the light emitter 11. The tip 210a of the suction mechanism 210 is directed in a direction toward the center 11b of the light emitting surface 11a from the tip 32a of the liquid guide part 32 when viewed in the direction of the optical axis A1. A tip direction of the suction mechanism 210 is the same as the tip direction of the liquid guide part 32 when viewed in the direction of the optical axis A1. The suction mechanism 210 is able to suction the air around the light emitting surface 11a in the direction approaching the liquid guide part 32. A suction pump or the like can be used as a power source of the suction mechanism 210.

The suction mechanism 210 can also be provided in the vicinity of the light receiver 12 (see FIG. 6). The suction mechanism 210 is able to suction the air around the light receiving surface 12a in the direction approaching the liquid guide part 42.

### Effects Achieved by Semiconductor Wafer Detection Device of Embodiment

In the semiconductor wafer detection device 300, the suction mechanism 210 is able to suction the air around the light emitting surface 11a and the light receiving surface 12a in the direction approaching the liquid guide parts 32 and 42. Hence, movement of a water droplet toward the liquid guide parts 32 and 42 can be facilitated. Accordingly, deterioration in detection accuracy due to the water droplet adhering to the light emitting surface 11a and the light receiving surface 12a can be suppressed.

In the semiconductor wafer detection device 300, the light emitting surface 11a and the light receiving surface 12a are inclined with respect to the horizontal plane. However, in the case where the suction mechanism 210 is used, water droplets can be removed even if the light emitting surface and the light receiving surface are not inclined with respect to the horizontal plane.

### Semiconductor Wafer Detection Device (Fourth Embodiment)

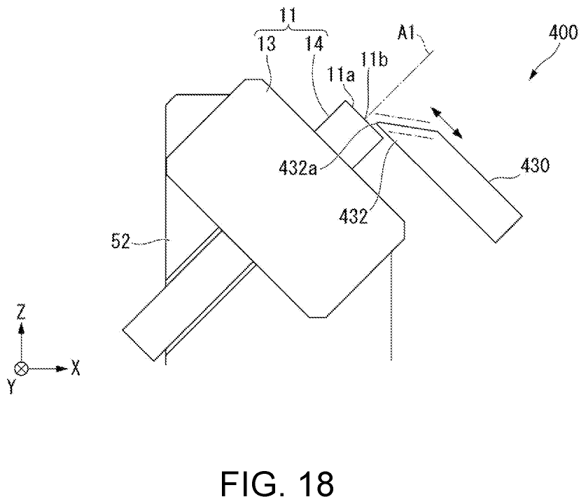

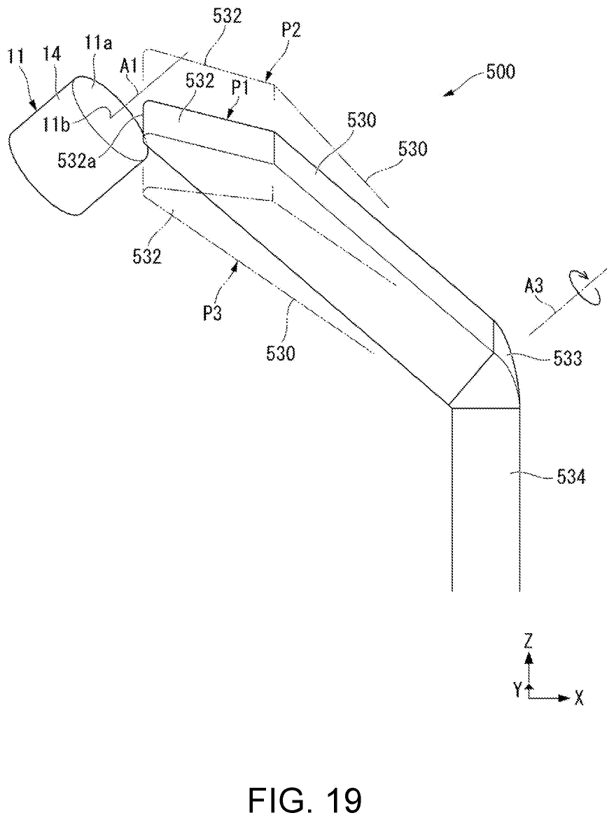

FIG. 18 is a side view partially illustrating a semiconductor wafer detection device 400 according to a fourth embodiment.

As illustrated in FIG. 18, the semiconductor wafer detection device 400 according to the present embodiment is provided with a droplet guide member 430 in place of the first droplet guide member 30. The droplet guide member 430 may also be provided in place of the second droplet guide member 40. The other configurations are similar to those of the semiconductor wafer detection device 100 (see FIG. 1).

The droplet guide member 430 is arranged in a posture with a tip 432a of a liquid guide part 432 facing the center 11b of the light emitting surface 11a when viewed in the direction of the optical axis A1. The droplet guide member 430 is slidable along the light emitting surface 11a of the light emitter 11. The droplet guide member 430 is movable in directions close to and away from the center 11b of the light emitting surface 11a when viewed in the direction of the optical axis A1.

### Effects Achieved by Semiconductor Wafer Detection Device of Embodiment

In the semiconductor wafer detection device 400, since the position of the droplet guide member 430 relative to the light emitter 11 and the light receiver 12 can be adjusted, depending on the usage environment, the droplet guide member 430 can be arranged at a position where a good water droplet removal effect is achieved. Accordingly, deterioration in detection accuracy due to water droplets can be suppressed.

### Semiconductor Wafer Detection Device (Fifth Embodiment)

FIG. 19 is a side view partially illustrating a semiconductor wafer detection device 500 according to a fifth embodiment.

As illustrated in FIG. 19, the semiconductor wafer detection device 500 according to the present embodiment is provided with a droplet guide member 530 in place of the first droplet guide member 30. The droplet guide member 530 may also be provided in place of the second droplet guide member 40. The other configurations are similar to those of the semiconductor wafer detection device 100 (see FIG. 1).

A base end of droplet guide member 530 is rotatably connected to an upper end of a pillar 534 via a hinge 533. The droplet guide member 530 is rotatable around a rotation axis A3 at the hinge 533. The rotation axis A3 is parallel to the optical axis A1. Hence, the liquid guide part 532 is rotatable within a plane parallel to the light emitting surface 11a.

A basic posture P1 illustrated in FIG. 19 is a posture of the droplet guide member 530, and is a posture in which a tip 532a of a liquid guide part 532 faces the center 11b of the light emitting surface 11a when viewed in the direction of the optical axis A1. A first rotation posture P2 is a posture of the droplet guide member 530 rotated by about 10° clockwise on the rotation axis A3 with respect to the basic posture P1. A second rotation posture P3 is a posture of the droplet guide member 530 rotated by about 350° clockwise on the rotation axis A3 with respect to the basic posture P1.

### Effects Achieved by Semiconductor Wafer Detection Device of Embodiment

In the semiconductor wafer detection device 500, since the droplet guide member 530 can be rotated within the plane parallel to the light emitting surface 11a, by rotation of the droplet guide member 530, water droplets can be removed from the light emitting surface 11a.

### Semiconductor Wafer Detection Device (Sixth Embodiment)

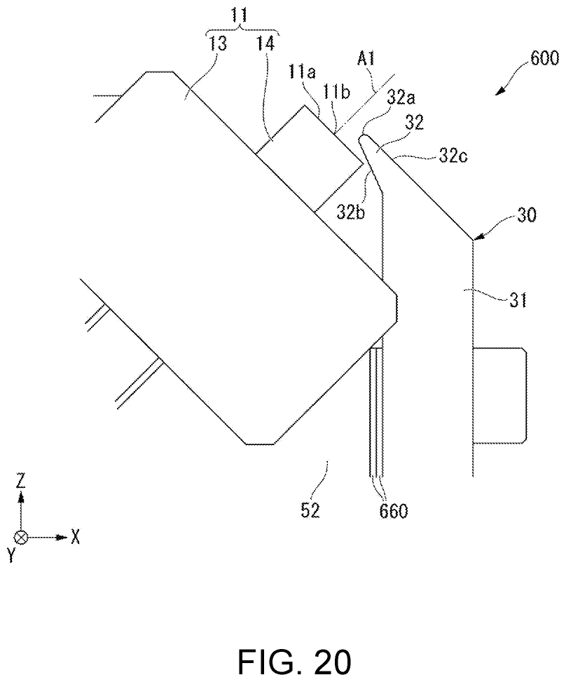

FIG. 20 is a side view partially illustrating a semiconductor wafer detection device 600 according to a sixth embodiment.

As illustrated in FIG. 20, in the semiconductor wafer detection device 600 according to the present embodiment, a spacer 660 for adjusting the position of the first droplet guide member 30 is provided between the first droplet guide member 30 and the first support frame 52. The spacer 660 may be provided between the second droplet guide member 40 and the extension frame 53B. The other configurations are similar to those of the semiconductor wafer detection device 100 (see FIG. 1).

The spacer 660 is of, for example, a plate shape. The number of the spacer 660 may be one or plural. The thickness and number of the spacer 660 can be determined depending on the desired positions of the droplet guide members 30 and 40. The spacer 660 is made of, for example, metal or resin.

In FIG. 20, if the thickness or number of the spacer 660 is small, the droplet guide member 30 is arranged at a position close to the light emitting surface 11a. If the thickness or number of the spacer 660 is large, the droplet guide member 30 is arranged at a position far from the light emitting surface 11a.

### Effects Achieved by Semiconductor Wafer Detection Device of Embodiment

In the semiconductor wafer detection device 600, the positions of the droplet guide members 30 and 40 relative to the light emitter 11 and the light receiver 12 can be adjusted by the spacer 660. Hence, depending on the usage environment, the droplet guide members 30 and 40 can be arranged at positions where a good water droplet removal effect is achieved. Accordingly, deterioration in detection accuracy due to water droplets can be suppressed.

The technical scope of the disclosure is not limited to the above embodiments, and various modifications can be made without departing from the spirit of the disclosure.

The light sensor 10 illustrated in FIG. 1 is a photointerrupter (transmission type photosensor). The photointerrupter detects the semiconductor wafer 1 by using a difference in the amount of light received between the case where the light from the light emitter 11 is blocked by the semiconductor wafer 1 and the case where the light is not blocked. The light sensor is not particularly limited if it is configured to be able to detect a semiconductor wafer by using light.

For example, the light sensor may be a photoreflector (reflective type photosensor). The photoreflector detects a semiconductor wafer by using reflected light generated when light from a light emitter is reflected by the semiconductor wafer. In the case where the light sensor is a photoreflector, a detector is able to detect the semiconductor wafer based on the amount of reflected light received by a light receiver. For example, in the case where the amount of reflected light received by the light receiver is lower than a predetermined value, the detector determines that no semiconductor wafer is present. In the case where the amount of light received by the light receiver is higher than or equal to the predetermined value, the detector determines that the semiconductor wafer is present.

The semiconductor wafer detection device 100 illustrated in FIG. 1 includes the first droplet guide member 30 that removes water droplets at the light emitter 11 and the second droplet guide member 40 that removes water droplets at the light receiver 12. However, the configuration of the semiconductor wafer detection device is not limited thereto. The semiconductor wafer detection device may include only one of the first droplet guide member and the second droplet guide member.

In the semiconductor wafer detection device 100 illustrated in FIG. 1, the light receiver 12 is located at a high position with respect to the light emitter 11. However, a positional relationship between the light emitter and the light receiver is not particularly limited. For example, the light receiver may be located at a lower position than the light emitter. Specifically, in FIG. 1, the light emitter 11 and the light receiver 12 May be swapped. In that case, the light from the light emitter is emitted in a diagonally downward direction (direction in which the light is inclined to descend as it goes in the −X direction).

The light receiver may be located above the light emitter. In this case, an emission direction of the light from the light emitter is upward. The light receiver may be located below the light emitter. In this case, the emission direction of the light from the light emitter is downward. The light receiver and the light emitter may be located at the same height. In this case, the emission direction of the light from the light emitter is approximately a horizontal direction.

In the embodiments described above, it is assumed that a water droplet adheres to the light emitter 11 and the light receiver 12. However, a droplet adhering to the light emitter and the light receiver may be a liquid different from water.

It is possible to replace the components in the embodiments described above with well-known components as appropriate without departing from the spirit of the disclosure. The embodiments or modifications described above may be combined as appropriate.

What is claimed is:

1. A semiconductor wafer detection device detecting a semiconductor wafer, comprising:
a light sensor, comprising a light emitter having a light emitting surface that emits light, and a light receiver having a light receiving surface that receives the light;
a detector, detecting the semiconductor wafer based on the light received by the light receiver; and
one or a plurality of droplet guide members, causing a droplet adhering to a sensor surface that is at least one of the light emitting surface and the light receiving surface to flow down, wherein
the one or plurality of droplet guide members comprise a liquid guide part of a plate shape, and
the liquid guide part is arranged with a tip facing a center of the sensor surface when viewed in an optical axis direction of the sensor surface.

2. The semiconductor wafer detection device according to claim 1, wherein
a portion of the liquid guide part that comprises at least the tip overlaps the sensor surface when viewed in the optical axis direction.

3. The semiconductor wafer detection device according to claim 1, wherein
a facing surface of the liquid guide part facing the sensor surface is an inclined surface that descends in a direction away from the sensor surface.

4. The semiconductor wafer detection device according to claim 1, wherein
the liquid guide part is formed in a blade shape whose thickness decreases toward the tip.

5. The semiconductor wafer detection device according to claim 1, further comprising:
a spraying mechanism, spraying a gas in a direction approaching the liquid guide part when viewed in the optical axis direction onto the sensor surface.

6. The semiconductor wafer detection device according to claim 1, further comprising:
a support, supporting both the light emitter and the light receiver.

7. A droplet guide member, used in a semiconductor wafer detection device equipped with a light sensor and a detector, the light sensor comprising a light emitter having a light emitting surface that emits light and a light receiver having a light receiving surface that receives the light, the detector detecting a semiconductor wafer based on the light received by the light receiver, wherein the droplet guide member comprises:
a liquid guide part of a plate shape, and
the liquid guide part is arranged with a tip facing a center of a sensor surface that is at least one of the light emitting surface and the light receiving surface when viewed in an optical axis direction of the sensor surface.
